(19) United States
(12) Patent Application Publication
(10) Pub. No.: US 2008/0149834 A1
(43) Pub. Date: Jun. 26, 2008

(54) Hot spot and ember detection system and method

(76) Inventors: Wayne Allen Bernhardt, Oshkosh, WI (US); Scott Hugo Delzer, Greenville, WI (US)

Correspondence Address: KIMBERLY-CLARK WORLDWIDE, INC.;Catherine E. Wolf, 401 NORTH LAKE STREET, NEENAH, WI, 54956, US

(21) Appl. No.: 11/644,416

(22) Filed: Dec. 22, 2006

(51) Int. Cl. H01L 31/00

(52) U.S. Cl. 250/330

(57) ABSTRACT

The present invention provides a system for detecting hot spots on a product being produced on a production line. The system has an infrared or near-infrared camera positioned proximate to a production line producing a product such that the camera can image the product being produced. Connected to the infrared or near-infrared camera and in communication with the infrared or near-infrared camera is a processing system. This processing system is able to process images generated by the infrared or near-infrared camera and determine if an ember or hot spot is present on the product being produced. Connected to the processing system is a response system, which is activated by the processing system when a hot spot is detected on the product being produced.

### FIELD OF THE INVENTION

The present invention relates generally to a system and a method for detecting hot spots and embers on rolled goods or other products produced on a production line.

### BACKGROUND OF THE INVENTION

During the production of rolled goods or other products produced on production lines, there exists a potential for hot embers to come into contact with the rolled good or product being produced. In some production lines, such as those producing products or materials which are non-flammable, embers are not as large of a problem; however, in the production of products or materials which are flammable, embers are a large problem. Embers may enter the production process from various sources, including, for example, mechanical components, such as bearings and the like. In addition, processes with dryers or other heating elements have a greater potential to produce embers as compared to processes without dryers or heating elements. When an ember comes into contact with a material which is flammable, the risk of a fire occurring is greatly increased. When an ember comes into contact with a material which is not flammable, the ember could damage the material, making the material unusable for its intended purpose.

One specific problem area is the production of rolled goods or materials which are flammable; such as paper rolls, including facial tissue, bath tissue and the like. Generally, paper is produced on large machines which produce large parent rolls. These parent rolls can often sit in a warehouse for an extended period of time before the parent rolls are converted into a usable product. If an ember is rolled up into one of these large parent rolls, the ember will often be given time to smolder and possibly start a fire in or on the roll, which could in turn result in the warehouse or manufacturing facility becoming involved in a fire. Such a fire could be financially devastating for a manufacturer of the rolled goods, or in the case where the rolled good is delivered to a converter or converting facility for further processing and converting into a useful product, devastating to the converter or converting facility. In addition, as with any fire, there is also the potential for the loss of life for employees of the manufacturer, warehouse, converter or those involved in fighting a fire.

A smothering ember can also cause a fire in a rolled good at the time of converting. Typically, in a converting process, a rolled good is unrolled from the parent roll for conversion into a useful product. When a rolled good with a smoldering ember wound in the roll is unwound for converting, air will come into contact with the smoldering ember. Often when a rolled good of a flammable material with an ember wound therein is unwound and air comes into contact with the smolder ember, the ember will cause the flammable material to ignite, resulting in a fire that could cause damage to converting machines or the buildings where the converting machines are located in which the conversion takes place.

There is a need in the art for a system and method for detecting embers on production lines of rolled goods and other products.

### SUMMARY OF THE INVENTION

Generally stated, the present invention provides a system for detecting hot spots on a product being produced on a production line. The system has an infrared or near-infrared camera positioned proximate to a production line producing a product such that the camera can image the product being produced. Connected to the infrared or near-infrared camera and in communication with the infrared or near-infrared camera is a processing system. This processing system is able to process images generated by the infrared or near-infrared camera and determine if an ember or hot spot is present on the product being produced. Connected to the processing system is a response system, which is activated by the processing system when a hot spot is detected on the product being produced.

The present invention also provides a method for detecting embers on a product being produced on a production line. In the method of detecting embers or hot spots of the present invention, an infrared or near-infrared camera is placed proximate to a production line producing a product. The camera images the product being produced on the production line while the product is on the production line to form infrared or near-infrared images of the product on the production line. Once the infrared or near-infrared images of the product on the production line are obtained, the infrared or near-infrared images are analyzed by a processing system to determine if an ember is present on the product. If an ember is found to be present on the product, the processing system of the present invention may activate a response system.

In one particular embodiment of the present invention, the camera used in both the system for detecting hot spots and the method of detecting embers on a product being formed on a production line is an infrared camera. The infrared camera produces infrared images of the product. The infrared camera may be a line scan camera or may be a two dimensional scan, also known as an area scan camera.

In another particular embodiment of the present invention, the processing system includes a host computer. This host computer has a communication input from the camera and a communication output to the response system. The host computer may further have a means to capture, store and/or display the images captured by the camera. The host computer may further have a video display device connected to the host computer. The video display device is capable of displaying an image generated from the infrared camera and is capable of replaying images captured from the infrared camera from the host computer.

### BRIEF DESCRIPTION OF THE DRAWINGS

FIG. 1 shows a diagram of the hot spot detection system of the present invention.

### DEFINITIONS

It should be noted that, when employed in the present disclosure, the terms “comprises”, “comprising” and other derivatives from the root term “comprise” are intended to be open-ended terms that specify the presence of any stated features, elements, integers, steps, or components, and are not intended to preclude the presence or addition of one or more other features, elements, integers, steps, components, or groups thereof.

As used herein, the term “hot spot” means a spot on the product being produced on a production line which is warmer than the remainder of the product. A hot spot could be a result of the process conditions used to produce the product or could be the result of an ember or other hot foreign body which has been deposited onto the product during the production process.

As used herein, the term “ember” means a particle or substance which is a fragment of a fire. Embers may be glowing pieces of metal, or other materials including flammable materials which are hot enough to start a fire with a larger portion of a flammable material as a fuel for a fire.

### DETAILED DESCRIPTION OF THE INVENTION

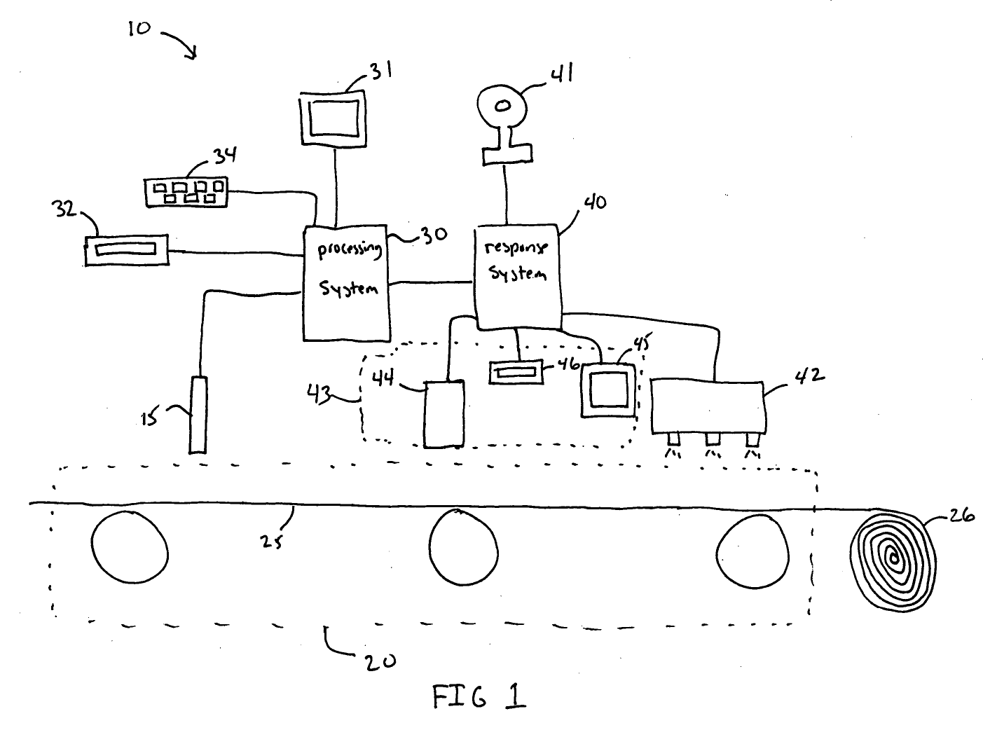

In order to obtain a better understanding of the present invention, attention is directed to the FIGURE. In the present invention, as is shown in FIG. 1, is a hot spot detection system 10. The system has an infrared or near-infrared camera 15 positioned proximate to a production line 20 producing a product 25 such that the camera can image the product 25 being produced. Connected to the infrared or near-infrared camera 15 and in communication with the infrared or near-infrared camera is a processing system 30. This processing system 30 serves to process the images generated by the infrared or near-infrared camera 15 and determine if an ember or hot spot is present on the product 25 being produced on the production line 20. Connected to the processing system is a response system 40. The response system 40 is activated by the processing system 30 when a hot spot is detected on the product 25 being produced.

To use the hot spot detection system 10 of the present invention, the system is connected such that the infrared or near-infrared camera 15 is positioned proximate to the product 25 being produced on the production line 20. The infrared or near-infrared camera 15 may be mounted anywhere along the production line 20, but is generally mounted near the end of the production line 20 just before the product 25 is packaged or the product 25 is rolled onto a roll 26. Other locations along the production line 20 where the infrared or near-infrared camera 15 may be suitably located is just after a dryer or other heating device or other production line equipment which may generate embers. In addition, the production line 20 may have more than one infrared or near-infrared camera 15 mounted proximate to the product being produced.

The infrared or near-infrared camera 15 mounted may be a line scan camera, which is a single linear array, or the infrared or near-infrared camera 15 may be a two dimensional area camera. In the present invention, either type of camera may be suitable used. Line scan cameras are generally preferred due to cost and since the line scan cameras adequately image the product being produced. Infrared cameras line scan cameras are effective in detecting and imaging embers or other hot spots down to a temperature of approximately 100° F. (37.8 C) with exposure times of less than about 0.2 milliseconds. As a result, infrared line scan cameras may be effectively used to detect embers or hot spots on a product being produced, even with line speeds up to about 4000 ft/min (1200 m/min) or more. Area infrared cameras also have a similar detection and imaging ability. Regarding near-infrared cameras, these cameras are very effective at detecting and imaging embers with shorter exposure times. However, the near-infrared cameras generally detect embers or hot spots down to about 450° F. (232 C). When embers or hot spots are less than about 450° F. (232 C), then the near-infrared camera may not be effective in detecting and imaging the embers or hot spots. As a result, infrared cameras are better suited for the detection system and process of the present invention. A combination of both infrared and near-infrared cameras may be used in the present invention to detect and image embers or hot spots. One commercial example of an infrared camera which may be used in the present invention is a MikroLine® 2256 high speed IR Line Camera, available from Mikron Infrared, which has offices in Hancock, Mich. This particular infrared camera has 256 data points per line and can measure up to 512 lines per second.

The infrared or near-infrared camera may be mounted proximate to the production line and should be mounted in a way so that the camera is adjustable. The camera should be mounted in such a way that the camera is able to obtain a desired field of view for the given application or product being produced. Camera mounts secure the camera in position and should allow adjustments to the camera. Generally, the camera mounts should allow the camera to be rotated, angled, or moved closer or further away from the product being produced on the production line. At the same time, the camera should be mounted in a way so that the camera does not move from its use position due to vibrations from the production line or be caused to be moved from its set position unintentionally. The camera mounts may also serve as a heat sink to dissipate heat away from the camera. In addition, the camera may be mounted above or below the product being produced, provided that the camera is able to view either side of the product being produced. Care should be taken that the camera does not image other heat sources which could interfere with the operation of the infrared or near-infrared cameras and the hot spot/ember detection system of the present invention.

The infrared or near-infrared camera 15 is connected to the processing system 30. Any type of connection may be used including a wireless connection, which uses a radio frequency to transmit the signal from the infrared or near-infrared camera 15 to the processing system 30. Other known connections, such as an ethernet connection, USB connection, a fiber optic connection or other similar connections may be used, provided that the selected connection is available from the camera to the processing system. Any connection that is available from the camera to the processing system may be used, provided that the signal will arrive in a short period of time that will allow the processing system to react to the signal received from the infrared or near-infrared camera.

The processing system 30 of the present invention may contain a host computer. The host computer serves to process the information generated by the infrared or near-infrared camera 15 and determine if a hot spot or ember is present on the product 25 being produced on the production line 20 under a control program loaded into the host computer of the processing system 30. The processing system may also contain a video display device 31 and a media storage device 32. The video display device 31 serves to display the infrared or near-infrared images captured by the infrared or near-infrared camera. A media storage device 32 is used to record and store images or other information received from the infrared or near-infrared camera 15. By “information” it is meant to include temperature or temperature profiles of the product being produced and the like. The processing system 30 may optionally serve to control the entire production line, certain portions of the production line or other equipment near the production line 20. The processing system may optionally record or track information received from other sensors that may be present on the production line 20, in addition to controlling or receiving information from other aspects of the entire production line 20.

The media storage device 32 may be a computer hard disk drive, an optical disk drive, such as a compact disc (CD) or a digital video disk (DVD), or any other device which is capable of storing images or other information recorded and received by the processing system 30 from the infrared or near-infrared camera 15. The images recorded by the media storage device of the processing system are captured as a series of continuous of infrared or near-infrared images captured by the camera 15. These images stored on the media storage device are typically stored for a period of time and then may be copied over. The period of time may be as short as a few minutes or up to 1 hour or more of production time. Generally, images older than 1 hour are no longer useful to the operator since the product 25 produces an hour in the past has been typically moved from the production line into a storage area or warehouse. The media storage device 32 may also be used to capture other data or information generated from other sensors or equipment on the production line.

The processing system 30 also allows the infrared or near-infrared images to be displayed on the video display device 31. The images may be displayed on the video display device 31 in real time and in a continuous manner as the images are captured by the infrared or near-infrared camera 15 or the images may be displayed on the video display device from the images stored on the media storage device 32 on a delayed basis. The processing system should also serve to allow the operator of the production line 20 to review and replay the images captured by the infrared or near-infrared camera 15 from the media storage device 32 at a slower speed than the speed of the images captured by the infrared or near-infrared camera. This will allow the operator to analyze the images captured, when a hot spot or ember is detected by the processing system 30 to make an assessment of whether or not an ember or hot spot is present on the product being produced on the production line. Generally, the operator will be able to play back one or more times the series of images captured by the media storage device 32 of the processing system 30. Typically, the operator will have an input or interface device 34, for example a keyboard or a mouse connected to the processing system which allows the operator to access the series of images stored on the media storage device 32 of the processing system 30.

The processing system 30 also may serve to control the infrared or near-infrared camera 15, for example, by changing the settings on the camera or by adjusting the location of the camera in relation to the product 25 being produced on the production line 20. In addition, the processing system 30 may also control or activate a response system 40, which is activated when a hot spot or ember is detected on the product being produced.

Generally, the processing system will analyze the images captured by the infrared or near-infrared camera. Typically, the host computer will be loaded with a software program that will analyze the images sent to the processing system. These software programs are generally available from suppliers of the cameras or the host computer systems.

The hot spot or ember detection system 10 of the present invention also has a response system 40, which is activated by the processing system 30 when a hot spot or ember is detected on the product 25 being produced on the production line 20. The response system 40 may be integrated into the processing system 30 or may be a stand alone system. If the response system 40 is a stand alone system, the response system should be in communication with the processing system 30. Any suitable connection may be used, including those described above for the connection of the processing system to the infrared or near-infrared camera 15. Generally, the response system 40 serves to alert one or more operators of the production line 20 that an ember or hot spot may be present and that action needs to be taken by the operator and/or to take corrective action to appropriately handle the threat posed by the possible presence of a hot spot or ember on the product being produced on the production line.

In one embodiment of the present invention, the response system 40 will activate an alarm 41, which will alert an operator of the production line of the possible presence of a hot spot or ember. The alarm may be an audible alarm or a visual alarm. Once receiving the alarm, the operator will take actions to determine or confirm that a hot spot or ember is present on the product being produced. One way the operator may determine if a hot spot or ember is present on the product being produced is the operator may review the series of infrared or near-infrared images captured by the camera 15 and stored on the media storage device 32. These images may be reviewed on the video display device 31 connected to the processing system. If the operator is of the opinion that corrective action is needed, the operator may start a new roll of product, in the case of rolled goods, or take action to locate the ember in the product produced, when the product is not a rolled good.

In an alternative embodiment, the response system 40 may activate a visual image web inspection system 43. The visual web inspection system 43 contains a camera 44, a media storage device 46, a video display device 45 and a host computer (not shown). The camera of the visual inspection system is one which captures visual images of the product being produced on the production line. Generally, the camera 44 is a high speed camera capable of taking a series of images of the product being produced. The camera may be an area camera or a line-scan camera and essentially can be any commercially available camera which has the capacity to take images of the product at production speeds.

It is noted that the video display device 45 of the visual web inspection system may be the same video display device of the processing system 30, or, in the alternative, may be a separate video display device. Likewise, the host computer of the visual inspection system 43 may be the same host computer of the processing system 30. Alternatively, the host computer of the visual inspection 43 system may be a separate computer from the host computer of the processing system 30.

When a hot spot or ember is detected by the processing system 30, the processing system activates the response system 40. The response system may activate the visual inspection system 43 to start recording visual images of the product being produced. A media storage device 46 is used to record and store visual images or captured from the camera 44. As with the infrared or near-infrared storage device, the images from the camera 44 are recorded by the media storage device 46 of the visual inspection system 43 and are recorded as a series of continuous images captured by the camera 44. The media storage device 46 may be a computer hard disk drive, an optical disk drive, such as a compact disc (CD) or a digital video disk (DVD), or any other device which is capable of storing images or other information recorded and received from the camera 44. These images stored on the media storage device are typically stored for a period of time and then may be copied over. The period of time may be as short as a few minutes or up to 1 hour or more of production time. Alternatively, the visual image recording system 43 may continuously record images and store images of the product being produced rather than being activated by the response system 40.

The visual inspection system 43 should also serve to allow the operator of the production line 20 to review and replay the images captured by the visual camera 44 and stored on the media storage device 46 at a slower speed than the speed of the images captured by the visual camera 44. This will allow the operator to analyze the images captured, when a hot spot or ember is detected by the processing system 30, to make an assessment of whether or not an ember or hot spot is present on the product being produced on the production line. Generally, the operator will be able to play back one or more times the series of images captured by the media storage device 46 of the visual inspection system 43. Typically, the operator will have an input or interface device 47, for example a keyboard or a mouse connected to the host computer of the response system, which allows the operator to access the series of images stored on the media storage device 46 of the visual inspection system 43.

The camera 44 of the visual inspection system 43 could be located downstream on the production line 20 from the infrared or near-infrared camera 15, as shown in FIG. 1, or the visual camera may be located upstream on the production line 20 from the infrared or near-infrared camera 15 (not shown). Generally, the visual camera 44, when present, should be located at a point where the camera 44 could capture a visual image of the hot spot or ember which may be present on the product being produced.

The visual camera 44 is connected to the visual inspection system 43. Any type of connection may be used including a wireless connection, which uses a radio frequency to transmit the signal from the infrared or near-infrared camera 15 to the processing system 30. Other known connections, such as an ethernet connection, a USB connection, a fiber optic connection or other similar connections may be used, provided that the connection is available from the camera to the processing system. Any connection that is available from the camera to the processing system may be used, provided that the signal will arrive in a short period of time that will allow the processing system to react to the signal received from the infrared or near-infrared camera. The other components of the visual inspection system are also connected to the systems using known connection methods.

Generally, the processing system 30 and the visual inspection system should be coordinated so that the visual inspection system retrieves images of the hot spot or ember when one is detected on the product being produced. This will allow the operator to go to the visual inspection system 43 and view images of the ember or hot spot in a relatively short time frame so that correction action may be taken in a timely manner, if corrective action is needed. This coordination may be accomplished by the use of computer software.

The visual inspection system 43 is generally used in conjunction with the alarm 41. However, the alarm 41 does not necessarily need to be used in conjunction with the visual inspection system.

In another alternative, the response system 40 may activate an extinguishing system 42, which could serve to extinguish or cool the hot spot or ember. The extinguishing system 42 may be any means that will effectively extinguish the ember. Examples of the extinguish systems include systems which will spray water onto the product, a curtain of carbon dioxide or any other means that will effectively extinguish an ember or cool a hot spot on a product on the production line. The extinguishing system 42 will need to be located downstream on the production line from the infrared or near-infrared camera. This is because the camera 15 will need to detect the ember or hot spot before the extinguishing system is activated, therefore requiring that the infrared or near-infrared camera be located upstream of the extinguishing system 42.

As with the visual inspection system 43, the extinguishing system 42 is generally used in conjunction with the alarm 41. However, the alarm 41 does not necessarily need to be used in conjunction with the extinguishing system.

It is possible, but not required, that each of the alarm, visual inspection system and the extinguishing system be used in combination with each other. All three may be used separately, but generally an alarm will be used to alert the operator of a potential problem caused by an ember or hot spot on the product being produced. In one particular embodiment, the response system may activate both an alarm and the visual inspection system. Another action taken by the response system may be to activate a marker system (not shown) which will clearly mark the product indicating that an ember or hot spot may be present on the product. This could alert operators of conversion lines to take extra care with the marked roll due to the presence of a possible ember or hot spot.

In addition to activating an alarm, extinguishing system or a visual inspection system, the response system 40 may also make adjustments to the process, for example, by starting a new roll of product, if the product being produced is a roll good, or may isolate the product so that the product with a detected ember or hot spot is placed in a location. As a result, the risk of a fire in the manufacturing facility or warehouse is reduced. Generally, in the case of roll goods, the roll of the product is generally taken outside or to another location within the manufacturing facility were fire suppression equipment is readily available and unrolled to a point where the ember or hot spot may be located and the potential of a fire may be kept in control. In the case of other products, the package or packages with the potential of having embers may be removed from the manufacturing facility or taken to a location where the potential for damage from a fire is reduced, such as a location in the manufacturing facility where fire suppression equipment is available.

To use the hot spot or ember detection system of the present invention, the infrared or near-infrared camera 15 is placed proximate to a production line 20 producing a product 25. The infrared or near-infrared camera 15 images the product 25 being produced on the production line, while the product is on the production line. This forms infrared or near-infrared images of the product on the production line. The infrared or near-infrared images are sent to the processing system 30, which analyzes the images to determine if a hot spot or ember is present on the product. If an ember or hot spot is found to be present on the product, the processing system 30 of the present invention may activate a response system 40, which in turn may alert an operator of the potential existence of an ember or hot spot on the product being produced, by way of an alarm. Alternatively, the response system 40 may take corrective action to effectively deal with the hot spot or ember on the product being produced.

In the present invention, the system and method may be useful on production lines producing products such as a-web of a material which is generally rolled after production or individual products which are packaged after production. In either case, generally the material being produced is flammable to some degree, but does not need to be flammable to use the system or method of the present invention. If a product is not flammable, generally to use the system or method of the present invention, the product will generally need to be adversely affected if an ember or hot spot is present on the product being produced. Examples of products which are generally rolled off the production line which may be inspected using the system and/or method of the present invention include, but are not limited to, paper products, films, metals, textiles, nonwovens and other similar materials which are currently produced and rolled after production. The system and/or method of the present invention may also be used on converting lines which convert materials into usable products, such as personal care products, including but not limited to bath tissue, facial tissue, diapers, training pants, feminine care products (sanitary napkins and tampons), adult incontinence products and wipes; clothing and other similar items.

Although the present invention has been described with reference to various embodiments, those skilled in the art will recognize that changes may be made in form and detail without departing from the spirit and scope of the invention. As such, it is intended that the foregoing detailed description be regarded as illustrative rather than limiting and that it is the appended claims, including all equivalents thereof, which are intended to define the scope of the invention.

1. A system for detecting hot spots on a product being produced on a production line, said system comprising
a. an infrared or near-infrared camera positioned proximate to a production line producing a product such that the camera can image the product being produced;
b. a processing system in communication with the camera, wherein the processing system processes the images from the camera to determine if a hot spot is present on the product being produced; and
c. response system in communication with the processing system; wherein the processing system activates the response system when a hot spot is detected on the product being produced.

2. The system for detecting hot spots according to claim 1, wherein the camera comprises an infrared camera.

3. The system for detecting hot spots according to claim 2, wherein the camera comprises a line-scan camera.

4. The system for detecting hot spots according to claim 2, wherein the camera comprises a two dimensional scan camera.

5. The system for detecting hot spots according to claim 2, wherein the processing system comprises a host computer, said host computer comprising a communication input from the camera and a communication output to the response system.

6. The system for detecting hot spots according to claim 5, wherein the host computer further comprises a means to capture, store and/or display the images captured by the camera.

7. The system for detecting hot spots according to claim 6, further comprising a video display device connected to the host computer, said video display device is capable of displaying an image generated from the infrared camera.

8. The system for detecting hot spots according to claim 2, wherein the response system comprises an alarm, an extinguishing system, a video web inspection system, or a combination thereof.

9. The system for detecting hot spots according to claim 8, wherein the response system comprises an alarm and a video web inspection system.

10. The system for detecting hot spots according to claim 1, wherein the camera comprises an infrared line-scan camera; the processing system comprises a host computer, said host computer comprising a communication input from the infrared line-scan camera and a communication output to the response system; and the response system comprises an alarm and a video web inspection system.

11. A process for detecting embers on a product being produced on a production line, said method comprising
a. providing an infrared or near-infrared camera proximate to a production line producing a product;
b. having the camera image the product being produced on the production line while the product is on the production line to produce infrared or near-infrared images of the product on the production line;
c. analyzing the infrared or near-infrared images of the product on the production line to determine if an ember is present on the product.

12. The process according to claim 11, further comprising
d. activating a response system when an ember is detected on the product being produced.

13. The process according to claim 11, wherein the camera is an infrared camera and the images are infrared images.

14. The process according to claim 12, wherein analyzing the infrared images is performed by a processing system, which is in communication with the infrared camera.

15. The process according to claim 14, wherein the processing system comprises a host computer, the host computer captures, stores the infrared images captured by the camera.

16. The process according to claim 15, further comprising activating a response system when an ember is detected on the product being produced.

17. The process according to claim 16, wherein activating the response system comprises activating an alarm, activating an extinguishing system, activating a video web inspection system to capture visible images of the product being produced, or a combination thereof.

18. The process according to claim 17, wherein activating the response system comprises activating an alarm, and activating a video web inspection system to capture visible images of the product being produced.
